(19) United States
(12) Patent Application Publication
(10) Pub. No.: US 2026/0136532 A1
(43) Pub. Date: May 14, 2026

(54) SEMICONDUCTOR DEVICE

(71) Applicant: Samsung Electronics Co., Ltd., Suwon-si (KR)

(72) Inventors: Inho Cha, Suwon-si (KR); Minsoo Kim, Suwon-si (KR); YONG KWAN KIM, Suwon-si (KR); HUI-JUNG KIM, Suwon-si (KR); JIHUN LEE, Suwon-si (KR); HYUNJIN LEE, Suwon-si (KR); HEEJAE CHAE, Suwon-si (KR)

(21) Appl. No.: 19/289,742

(22) Filed: Aug. 4, 2025

(30) Foreign Application Priority Data
Nov. 11, 2024 (KR) 10-2024-0159380

(51) Int. Cl. H10B 12/00

(52) U.S. Cl. CPC H10B 12/315; H10B 12/05

(57) ABSTRACT

A semiconductor device includes a bit line, a vertical active pattern on the bit line and extending lengthwise, a word line extending lengthwise in a first horizontal direction and overlapping the vertical active pattern in a second horizontal direction, a gate insulating pattern provided in a space between the word line and the vertical active pattern, an electric field generating pattern provided next to the vertical active pattern in the first and second horizontal directions, and a buffer layer located in a space between the vertical active pattern and the electric field generating pattern in the first and second horizontal directions. The electric field generating pattern has a strain gradient from an interface between the buffer layer and the electric field generating pattern toward an inside of the electric field generating pattern. The strain gradient induces an electric polarization in the electric field generating pattern.

### CROSS-REFERENCE TO RELATED APPLICATION(S)

This U.S. non-provisional application claims priority under 35 USC § 119 to Korean Patent Application No. 10-2024-0159380, filed on Nov. 11, 2024, in the Korean Intellectual Property Office, the disclosure of which is herein incorporated by reference in its entirety.

### BACKGROUND

The present disclosure relates to a semiconductor device, and more specifically, to a semiconductor device including a vertical channel transistor.

In order to satisfy excellent performance and economic efficiency, it is required to reduce sizes and design rules of semiconductor devices and increase the integration of the semiconductor devices. Various methods are being studied to form the semiconductor devices with excellent performance while overcoming the limitations due to the high integration of the semiconductor devices. Accordingly, vertical channel type transistors have been proposed to increase the integration of transistors in semiconductor devices.

### SUMMARY

The present disclosure is directed to providing a semiconductor device including a vertical channel transistor with improved electrical characteristics.

According to an aspect of the present disclosure, a semiconductor device includes a bit line, a vertical active pattern on an upper surface of the bit line and extending lengthwise in a vertical direction perpendicular to the upper surface of the bit line, a word line extending lengthwise in a first horizontal direction and overlapping a first side surface of the vertical active pattern in a second horizontal direction different from the first horizontal direction, the first horizontal direction and the second horizontal direction being perpendicular to the vertical direction, a gate insulating pattern provided in a space between the word line and the first side surface of the vertical active pattern, an electric field generating pattern provided next to the vertical active pattern in the first horizontal direction and the second horizontal direction, and a buffer layer located in a space between the vertical active pattern and the electric field generating pattern in the first horizontal direction and the second horizontal direction. The electric field generating pattern has a strain gradient from an interface between the buffer layer and the electric field generating pattern toward an inside of the electric field generating pattern. The strain gradient induces an electric polarization in the electric field generating pattern.

According to an aspect of the present disclosure, a semiconductor device includes a plurality of first vertical active patterns arranged in a first direction, a plurality of second vertical active patterns arranged in the first direction, the plurality of second vertical active patterns being spaced apart from the plurality of first vertical active patterns in a second direction intersecting the first direction, wherein each first vertical active pattern of the plurality of first vertical active patterns extends lengthwise in a vertical direction perpendicular to the first direction and the second direction, a first word line provided next to a first side of each first vertical active pattern of the plurality of first vertical active patterns and extending lengthwise in the first direction, a second word line provided next to a first side of each second vertical active pattern of the plurality of second vertical active patterns and extending lengthwise in the first direction, a gate insulating pattern provided between the first word line and each first vertical active pattern of the plurality of first vertical active patterns and between the second word line and each second vertical active pattern of the plurality of second vertical active patterns, an electric field generating pattern adjacent to the plurality of first vertical active patterns and the plurality of second vertical active patterns, and a buffer layer contacting the electric field generating pattern. The electric field generating pattern has a strain gradient from an interface between the buffer layer and the electric field generating pattern toward an inside of the electric field generating pattern. The strain gradient induces an electric polarization in the electric field generating pattern.

According to an aspect of the present disclosure, a semiconductor device includes a vertical active pattern extending lengthwise in a vertical direction, a word line extending lengthwise in first direction and overlapping a first side surface of the vertical active pattern in a second direction different from the first direction, wherein the vertical direction is perpendicular to the first direction and the second direction, a gate insulating pattern provided in a space between the word line and the first side surface of the vertical active pattern, an electric field generating pattern provided next to the vertical active pattern in the first direction and the second direction, and a buffer layer located in a space between the vertical active pattern and the electric field generating pattern. The electric field generating pattern has a strain gradient from an interface between the buffer layer and the electric field generating pattern toward an inside of the electric field generating pattern. The strain gradient induces an electric polarization in the electric field generating pattern. The vertical active pattern includes a first source/drain region that is an upper side portion of the vertical active pattern, a second source/drain region that is a lower side portion of the vertical active pattern, and a channel region located between the first source/drain region and the second source/drain region and including a portion that overlaps the word line in a horizontal direction. The electric field generating pattern is provided next to the channel region.

### BRIEF DESCRIPTION OF DRAWINGS

FIG. 1 is a plan view of a semiconductor device according to one embodiment of the present disclosure.

FIG. 2 is a perspective view of the semiconductor device according to one embodiment of the present disclosure.

FIG. 3A is a cross-sectional view taken along line I-I′ of FIG. 1.

FIG. 3B is a cross-sectional view taken along line II-II′ of FIG. 1.

FIG. 4A is a cross-sectional view of a semiconductor device according to one embodiment of the present disclosure, and is a cross-sectional view corresponding to line I-I′ of FIG. 1.

FIG. 4B is a cross-sectional view of the semiconductor device according to one embodiment of the present disclosure, and is a cross-sectional view corresponding to line II-II′ of FIG. 1.

FIGS. 5A to 13A are cross-sectional views for showing a manufacturing method of a semiconductor device according to one embodiment of the present disclosure, and are cross-sectional views corresponding to line I-I′ of FIG. 1.

FIGS. 5B to 13B, 14, and 15 are cross-sectional views for showing the manufacturing method of a semiconductor device according to one embodiment of the present disclosure, and are cross-sectional views corresponding to line II-II′ of FIG. 1.

FIG. 16A is a cross-sectional view of a semiconductor device according to one embodiment of the present disclosure, and is a cross-sectional view corresponding to line I-I′ of FIG. 1.

FIG. 16B is a cross-sectional view of the semiconductor device according to one embodiment of the present disclosure, and is a cross-sectional view corresponding to line II-II′ of FIG. 1.

FIG. 17A is a cross-sectional view of a semiconductor device according to one embodiment of the present disclosure, and is a cross-sectional view corresponding to line I-I′ of FIG. 1

FIG. 17B is a cross-sectional view of the semiconductor device according to one embodiment of the present disclosure, and is a cross-sectional view corresponding to line II-II′ of FIG. 1.

### DETAILED DESCRIPTION

Hereafter, the embodiments of the present disclosure will be clearly and thoroughly described with reference to the accompanying drawings.

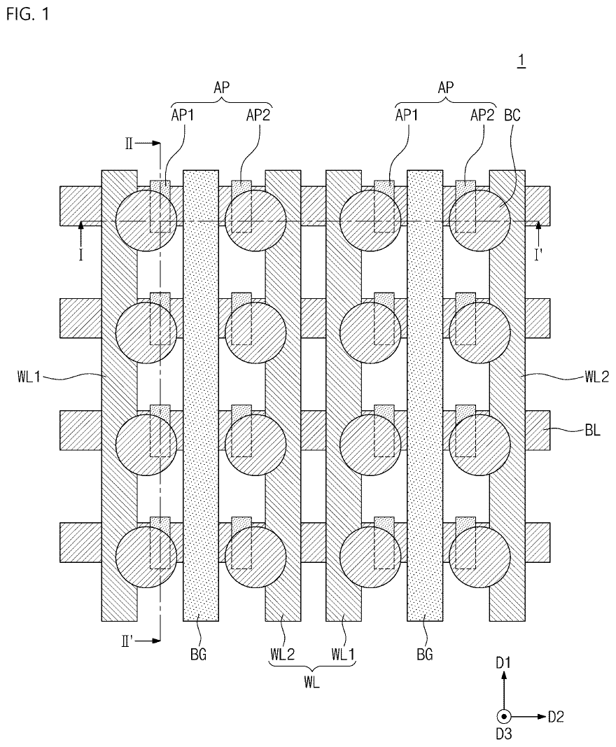

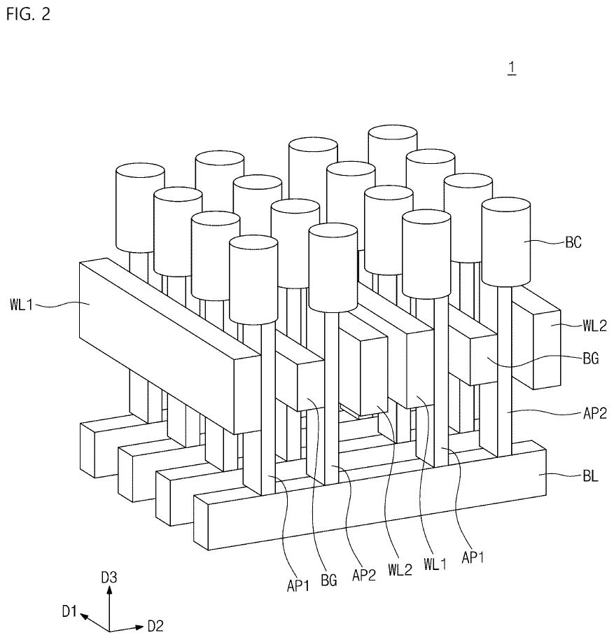

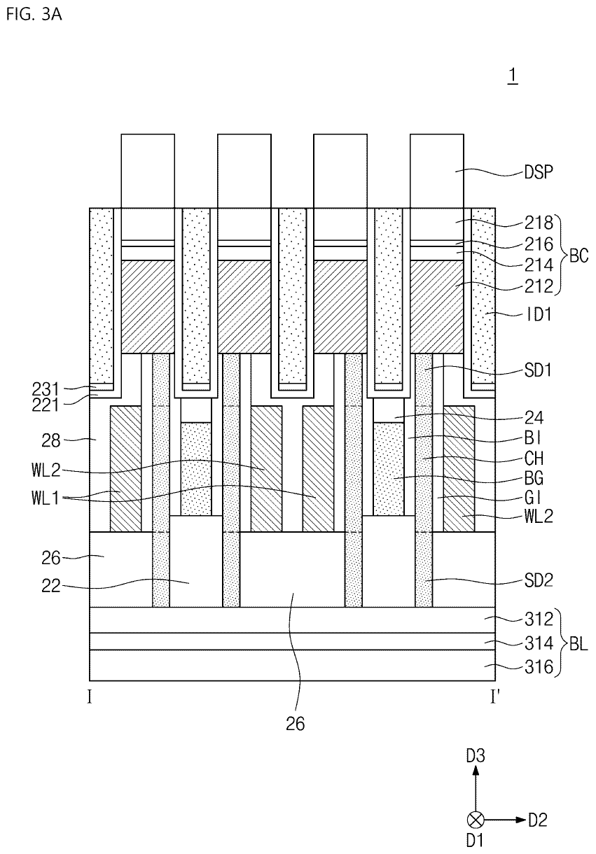

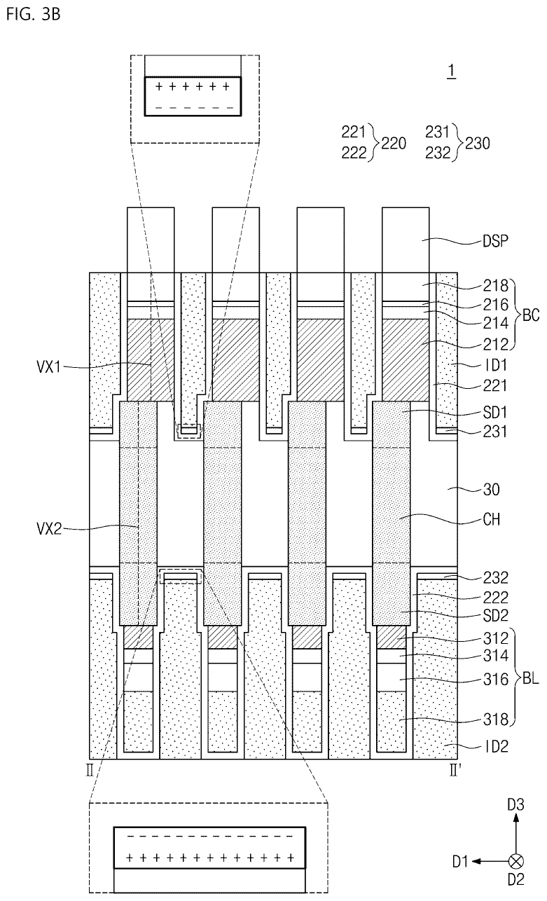

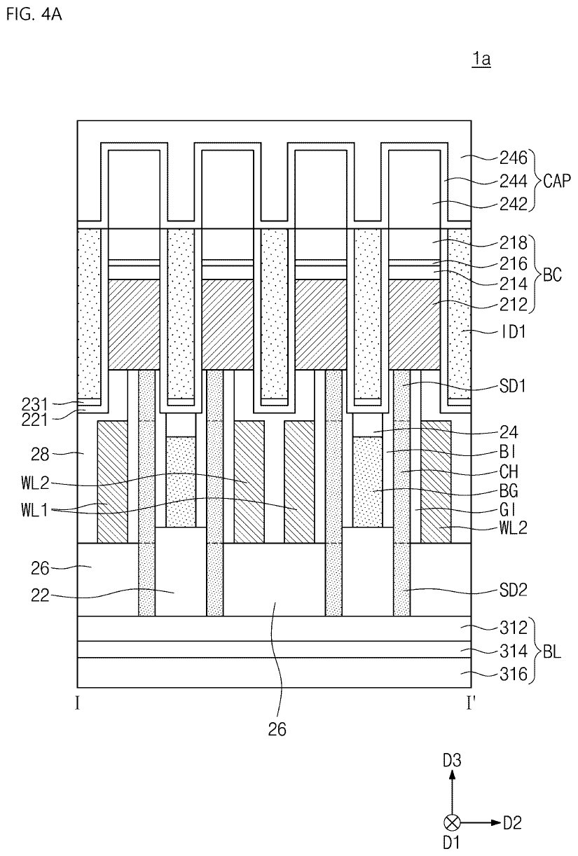

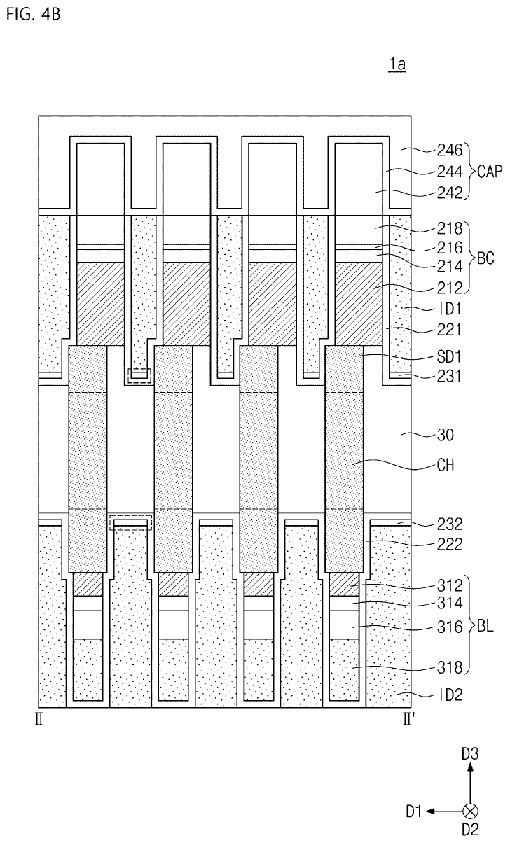

FIG. 1 is a plan view of a semiconductor device 1 according to one embodiment of the present disclosure. FIG. 2 is a perspective view of the semiconductor device 1 according to one embodiment of the present disclosure. FIG. 3A is a cross-sectional view taken along line I-I′ of FIG. 2. FIG. 3B is a cross-sectional view taken along line II-II′ of FIG. 2.

Referring to FIGS. 1 to 3B, the semiconductor device 1 may include memory cells that include a vertical channel transistor (VCT).

Vertical active patterns AP may be arranged in a first direction D1 (i.e., a first horizontal direction). The vertical active patterns AP may be arranged in a second direction D2 (i.e., a second horizontal direction). The second direction D2 may intersect the first direction D1. For example, the second direction D2 may be perpendicular to the first direction D1. The vertical active patterns AP may extend in a third direction D3 (i.e., a vertical direction) which is perpendicular to an upper surface of a bit line BL. The third direction D3 may intersect the first direction D1 and the second direction D2. For example, the third direction D3 may be perpendicular to the first direction D1 and the second direction D2. The third direction D3 may be referred to as a vertical direction or an up-down direction.

The vertical active patterns AP may include a semiconductor material. For example, each of the vertical active patterns AP may include silicon (Si), germanium (Ge), or silicon-germanium (Si—Ge). In one embodiment, the vertical active patterns AP may be in a crystalline state (in particular, a single-crystalline state). For example, each of the vertical active patterns AP may include crystalline silicon, more specifically, single-crystalline silicon.

The vertical active patterns AP may include first vertical active patterns AP1 and second vertical active patterns AP2. The first vertical active patterns AP1 may be arranged in the first direction D1. The second vertical active patterns AP2 may be arranged in the first direction D1. The first vertical active patterns AP1 may be arranged in the second direction D2. The second vertical active patterns AP2 may be arranged in the second direction D2. The second vertical active patterns AP2 may be arranged between the first vertical active patterns AP1 arranged in the second direction D2. For example, the first vertical active patterns AP1 and the second vertical active patterns AP2 may be alternately arranged in the second direction D2.

A structure of the first vertical active pattern AP1 and a structure of the second vertical active pattern AP2 may be substantially the same. For example, a width of the first vertical active pattern AP1 may be substantially the same as a width of the second vertical active pattern AP2, and a height of the first vertical active pattern AP1 may be substantially the same as a height of the second vertical active pattern AP2.

The vertical active pattern AP may include a first source/drain region SD1, a second source/drain region SD2, and a channel region CH between the first source/drain region SD1 and the second source/drain region SD2. For example, the first source/drain region SD1 may be an upper side portion of the vertical active pattern AP, and the second source/drain region SD2 may be a lower side portion of the vertical active pattern AP. The channel region CH is a portion located between the first source/drain region SD1 and the second source/drain region SD2 and may overlap a word line WL in a horizontal direction, for example, in the second direction D2.

The first source/drain region SD1 may be provided in a portion of the vertical active pattern AP. Specifically, the first source/drain region SD1 may be provided at one end portion of the vertical active pattern AP in an extending direction of the vertical active pattern AP. For example, the first source/drain region SD1 may be provided at an upper portion of the vertical active pattern AP.

The second source/drain region SD2 may be provided in another portion of the vertical active pattern AP. Specifically, the second source/drain region SD2 may be provided at the other end portion of the vertical active pattern AP in the extending direction of the vertical active pattern AP. For example, the second source/drain region SD2 may be provided at a lower portion of the vertical active pattern AP.

The channel region CH may be provided in the remaining portion of the vertical active pattern AP. Specifically, the channel region CH may be provided in an intermediate portion of the vertical active pattern AP. The channel region CH may be defined by the first source/drain region SD1 and the second source/drain region SD2. For example, the channel region CH may be defined between the first source/drain region SD1 provided at the upper portion of the vertical active pattern AP and the second source/drain region SD2 provided at the lower portion of the vertical active pattern AP.

The channel region CH may have a first conductivity type (for example, a p-type) or may be in an undoped state. The first and second source/drain regions SD1 and SD2 may be dopant regions having a second conductivity type (for example, a n-type).

The word line WL may be provided next to the vertical active patterns AP in the second direction D2. The word line WL may extend lengthwise in one direction. The one direction may be the first direction D1. The word line WL may cross one side surfaces of the vertical active patterns AP.

A plurality of word lines WL may be provided. The word lines WL may be arranged in the second direction D2.

The word line WL may include a first word line WL1 provided at one side of the first vertical active pattern AP1 and a second word line WL2 provided at one side of the second vertical active pattern AP2. The first word line WL1 and/or the second word line WL2 may be provided as a plurality of first word lines and second word lines according to the arrangement of the first vertical active patterns AP1 and the second vertical active patterns AP2.

The first word line WL1 may be provided on one side of the first vertical active patterns AP1 arranged in the first direction D1. The first word line WL1 may be provided at one sides of the channel regions CH of the first vertical active patterns AP1. The first word line WL1 may be spaced apart from the first vertical active patterns AP1. For example, the first word line WL1 may be spaced apart from the first vertical active patterns AP1 in a direction opposite to the second direction D2.

The second word line WL2 may be provided at one sides of the second vertical active patterns AP2 arranged in the first direction D1. The second word line WL2 may be provided on one sides of the channel regions CH of the second vertical active patterns AP2. The second word line WL2 may be spaced apart from the second vertical active patterns AP2. For example, the second word line WL2 may be spaced apart from the second vertical active patterns AP2 in the second direction D2.

The word line WL may include doped polysilicon, a metal, a conductive metal nitride, a conductive metal silicide, a conductive metal oxide, or a combination thereof.

A gate insulating pattern GI may be provided between the word line WL and the vertical active pattern AP. The gate insulating pattern GI may extend in the first direction D1. A plurality of gate insulating patterns GI may be provided. For example, the gate insulating patterns GI may each be provided between the word lines WL and the vertical active patterns AP. The gate insulating pattern GI may include a silicon oxide.

The gate insulating pattern GI may contact one side surfaces of the first vertical active patterns AP1. In this case, the gate insulating pattern GI may also contact one side surface of the first word line WL1. The gate insulating pattern GI may contact one side surfaces of the second vertical active patterns AP. In this case, the gate insulating pattern GI may also contact one side surface of the second word line WL2.

The first vertical active patterns AP1 and the second vertical active patterns AP2 may be provided between the first word line WL1 and the second word line WL2. The first vertical active patterns AP1 and the second vertical active patterns AP2 may be provided between the gate insulating pattern GI in contact with one side surface of the first word line WL1 and the gate insulating pattern GI in contact with one side surface of the second word line WL2.

A back gate electrode BG may be provided between the first vertical active pattern AP1 and the second vertical active pattern AP2. Specifically, the back gate electrode BG may be provided between the first vertical active patterns AP1 arranged in the first direction D1 and the second vertical active patterns AP2 arranged in the first direction D1. The back gate electrode BG may extend in the first direction D1.

The back gate electrode BG may be provided at the other side of the first vertical active pattern AP1 and the other side of the second vertical active pattern AP2. The back gate electrode BG may be spaced apart from the first vertical active pattern AP1 and the second vertical active patterns AP2 that are adjacent to each other in the second direction D2.

For example, the back gate electrode BG may include doped polysilicon, a conductive metal nitride, a metal, a conductive metal silicide, a conductive metal oxide, or a combination thereof.

A negative voltage may be applied to the back gate electrode BG during the operation of the semiconductor device 1 and the back gate electrode BG may increase a threshold voltage of the VCT.

A back gate insulating pattern BI may be provided between the back gate electrode BG and the first vertical active pattern AP1. The back gate insulating pattern BI may be provided between the back gate electrode BG and the second vertical active pattern AP2. The back gate insulating pattern BI may allow the back gate electrode BG to be spaced apart from the first vertical active pattern AP1 and the second vertical active pattern AP2. The back gate electrode BG may include a silicon oxide.

The back gate insulating pattern BI may contact the other side surface of the first vertical active pattern AP1 and/or the other side surface of the second vertical active pattern Ap2. The back gate insulating pattern BI may contact one side surface and the other side surface of the back gate electrode BG. In this case, one side surface and the other side surface of the back gate electrode BG may face each other. For example, the back gate electrode BG may be shared by two adjacent active patterns AP1 and AP2 neighboring in the second direction D2.

Accordingly, the channel region CH of the vertical active pattern AP may be controlled by the word line WL and the back gate electrode BG during the operation of the semiconductor device 1.

Each of contact patterns BC may be provided on one of the vertical active patterns AP. Each of the contact patterns BC may be provided on a corresponding one of the first vertical active patterns AP1 and the second vertical active patterns AP2. Specifically, the contact patterns BC may be provided on the first source/drain regions SD1 of the vertical active patterns AP. The contact patterns BC may be separated from each other by a first interlayer insulating film ID1. Each of the contact patterns BC may have various shapes such as a circular shape, an elliptical shape, a rectangular shape, and a square shape in a plan view.

The contact pattern BC may extend in the third direction D3. For example, the contact pattern BC may vertically extend. A first virtual vertical central axis VX1 of the contact pattern BC may be offset from a second virtual vertical central axis VX2 of the vertical active pattern AP. Specifically, the first virtual vertical central axis VX1 may be offset from the second virtual vertical central axis VX2 in a longitudinal direction of the word line WL. More specifically, the first virtual vertical central axis VX1 may be offset from the second virtual vertical central axis VX2 in a direction opposite to the first direction D1.

The first virtual vertical central axis VX1 and the second virtual vertical central axis VX2 may be parallel to the third direction D3. The first virtual vertical central axis VX1 may pass through a center of the contact pattern BC. The second virtual vertical central axis VX2 may pass through a center of the vertical active pattern AP. In an embodiment, when viewed in a plan view as shown in FIG. 1, a center of the vertical active pattern AP may be distant from a center of the contact pattern BC in a diagonal direction between the first direction D1 and the second direction D2.

The contact patterns BC may contact upper surfaces of the vertical active patterns AP. The contact pattern BC may contact a portion of the upper surface of the vertical active pattern AP. The remaining portion of the upper surface of the vertical active pattern AP may not contact the contact pattern BC. The remaining portion of the upper surface of the vertical active pattern AP may contact a first buffer layer 221 described below.

In one embodiment, the contact pattern BC may be a stacked structure sequentially including a buffer semiconductor pattern 212, a first doped semiconductor pattern 214, a first barrier pattern 216, and a first low resistance pattern 218.

The buffer semiconductor pattern 212 may vertically extend. The buffer semiconductor pattern 212 may come into contact with the first source/drain region SD1. The buffer semiconductor pattern 212 may include a polycrystalline semiconductor material (e.g., polysilicon). The buffer semiconductor pattern 212 may be doped with dopants.

The buffer semiconductor pattern 212 may be provided so that its doping concentration gradually changes in the vertical direction. Specifically, an internal doping concentration of the buffer semiconductor pattern 212 may decrease as it moves away from the first doped semiconductor pattern 214. The internal doping concentration of the buffer semiconductor pattern 212 may increase as it moves away from the first source/drain region SD1.

The first doped semiconductor pattern 214 may be stacked on the buffer semiconductor pattern 212. The first doped semiconductor pattern 214 may include a semiconductor material highly doped with n-type dopants or p-type dopants. The first doped semiconductor pattern 214 may include a polycrystalline semiconductor material. For example, the first doped semiconductor pattern 214 may include polysilicon.

A dopant concentration of the first doped semiconductor pattern 214 may be higher than a dopant concentration of the buffer semiconductor pattern 212, and the dopant concentration of the buffer semiconductor pattern 212 may be higher than a dopant concentration of the first source/drain region SD1.

The first barrier pattern 216 and the first low resistance pattern 218 may be sequentially stacked on the first doped semiconductor pattern 214.

The first barrier pattern 216 may include at least one of a metal and a metal nitride. For example, the first barrier pattern 216 may include Ti, Ta, TiN, TaN, Ti/TiN, or Ta/TaN. The first low resistance pattern 218 may be formed of a material having a lower resistance than the first barrier pattern 216. For example, the first low resistance pattern 218 may include tungsten.

Bit lines BL may be provided on lower surfaces of the vertical active patterns AP. Each of the bit lines BL may be provided under the first vertical active patterns AP1 and the second vertical active patterns AP2 that are alternately arranged. The bit lines BL may extend in the second direction D2 and may be arranged in the first direction D1. The bit lines BL may be spaced apart from each other in the first direction D1.

Each of the bit lines BL may include a second doped semiconductor pattern 312 provided on lower surfaces of the first and second vertical active patterns AP1 and AP2 that are alternately arranged, a second barrier pattern 314 provided on a lower surface of the second doped semiconductor pattern 312, and a second low resistance pattern 316, which are sequentially stacked.

The second doped semiconductor pattern 312 may come into contact with the second source/drain region SD2. The second doped semiconductor pattern 312 may include a polycrystalline semiconductor material. For example, the second doped semiconductor pattern 312 may include polysilicon.

The second barrier pattern 314 may be stacked on the second doped semiconductor pattern 312. The second low resistance pattern 316 may be stacked on the second barrier pattern 314. The second low resistance pattern 316 may include a conductive metal nitride, a metal silicide, or a metal. For example, the second low resistance pattern 316 may include tungsten.

Each of the bit lines BL may further include a capping pattern 318 stacked on the second low resistance pattern 316. The capping pattern 318 may include an insulating material such as a silicon nitride and a silicon oxynitride.

The bit lines BL may contact the lower surfaces of the vertical active patterns AP. The bit line BL may contact a portion of the lower surface of the vertical active pattern AP. The remaining portion of the lower surface of the vertical active pattern AP may not contact the bit line BL. The remaining portion of the lower surface of the vertical active pattern AP may contact a second buffer layer 222 described below.

An electric field generating pattern 230 may be provided next to the vertical active pattern AP in the first direction D1 as shown in FIG. 3B and the second direction D2 as shown in FIG. 3A. The electric field generating pattern 230 may be adjacent to the vertical active pattern AP. Specifically, the electric field generating pattern 230 may be provided next to the first source/drain region SD1 and/or the second source/drain region SD2 of the vertical active pattern AP in the first direction D1 and the second direction D2. For example, a first electric field generating pattern 231 may be provided next to the first source/drain region SD1 in the first direction D1 and the second direction D2. A second electric field generating pattern 232 may be provided next to the second source/drain region SD2 in the first direction D1 and the second direction D2.

In one embodiment, the first electric field generating pattern 231 and the second electric field generating pattern 232 may be selectively provided. For example, only one of the first electric field generating pattern 231 and the second electric field generating pattern 232 may be provided.

In one embodiment, the first electric field generating pattern 231 may be located below an upper end of the first source/drain region SD1. The first electric field generating pattern 231 may be located above a lower end of the first source/drain region SD1. In an embodiment, a lower surface of the first electric field generating pattern 231 may be disposed at a level higher than a boundary between the first source/drain region SD1 and the channel region CH, and an upper surface of the first electric field generating pattern 231 may be disposed at a level lower than a boundary between the first source/drain region SD1 and the contact pattern BC.

In one embodiment, the second electric field generating pattern 232 may be located below an upper end of the second source/drain region SD2. The second electric field generating pattern 232 may be located above a lower end of the second source/drain region SD2. In an embodiment, a lower surface of the second electric field generating pattern 232 may be disposed at a level higher than a boundary between the second source/drain region SD2 and the bit line BL, and an upper surface of the second electric field generating pattern 232 may be disposed at a level lower than a boundary between the second source/drain region SD2 and the channel region CH.

In one embodiment, the first electric field generating pattern 231 may not overlap the contact pattern BC in the vertical direction. For example, the first electric field generating pattern 231 may be arranged to avoid overlapping the contact pattern BC in the vertical direction D3. In one embodiment, the second electric field generating pattern 232 may not overlap the bit line BL in the vertical direction D3. For example, the second electric field generating pattern 232 may be arranged to avoid overlapping the bit line BL in the vertical direction D3.

The electric field generating pattern 230 may be provided between the vertical active patterns AP. Specifically, the electric field generating pattern 230 may surround the vertical active pattern AP in a plan view. For example, the first electric field generating pattern 231 may surround the first source/drain region SD1 in a plan view, and the second electric field generating pattern 232 may surround the second source/drain region SD2 in a plan view. In an embodiment, the first electric field generating pattern 231 may be adjacent to the first source/drain region SD1 in the first direction D1 and the second direction D2, and the second electric field generating pattern 232 may be adjacent to the second source/drain region SD2 in the first direction D1 and the second direction D2.

The electric field generating pattern 230 may include a dielectric material. For example, the electric field generating pattern 230 may include BiFeO₃, TiO₂, BaTiO₃, BaSrTiO₃, PbMgNbO₃, PbSrTiO₃, or Pb(Zr, Ti)O₃. A material of the first electric field generating pattern 231 and a material of the second electric field generating pattern 232 may be substantially the same. However, the present disclosure is not limited thereto, and the material of the first electric field generating pattern 231 may differ from the material of the second electric field generating pattern 232 as needed. Accordingly, the electric field intensity applied to the first source/drain region SD1 may differ from the electric field intensity applied to the second source/drain region SD2.

A buffer layer 220 may be provided next to the vertical active pattern AP in the first direction D1 and second direction D2. The buffer layer 220 may generate electrical polarization in the electric field generating pattern 230. Specifically, the buffer layer 220 may contact the electric field generating pattern 230, and accordingly, a strain gradient may occur in the electric field generating pattern 230.

An electric field may be generated in the semiconductor device 1 by the electrical polarization generated in the electric field generating pattern 230. This may be based on flexoelectric effect, but the present disclosure is not limited thereto, and the electric field generating pattern 230 may generate an electric field by various methods.

The buffer layer 220 may contact the electric field generating pattern 230. The buffer layer 220 may include a first buffer layer 221 in contact with the first electric field generating pattern 231 and a second buffer layer 222 in contact with the second electric field generating pattern 232. Therefore, the first buffer layer 221 may generate electrical polarization in the first electric field generating pattern 231 and the second buffer layer 222 may generate electrical polarization in the second electric field generating pattern 232.

In one embodiment, the first buffer layer 221 and the second buffer layer 222 may be selectively provided. For example, only one of the first buffer layer 221 and the second buffer layer 222 may be provided.

In one embodiment, the buffer layer 220 may be provided under the electric field generating pattern 230. However, the buffer layer 220 is not limited thereto, and the buffer layer 220 may also be provided on the electric field generating pattern 230. For example, the first buffer layer 221 may be provided under the first electric field generating pattern 231. The second buffer layer 222 may be provided on the second electric field generating pattern 232.

A material of the buffer layer 220 may differ from a material of the electric field generating pattern 230. A lattice constant of the material of the buffer layer 220 may differ from a lattice constant of the material of the electric field generating pattern 230. For example, the buffer layer 220 may include SrTiO₃, SrRuO\grave{ }, W, Ti, or Au. In an embodiment, due to mismatch between a lattice constant of the buffer layer 220 and a lattice constant of the electric field generating pattern 230 in the formation of the electric field generating pattern 230, the electric field generating pattern 230 may have a strain gradient from an interface between the buffer layer 220 and the electric field generating pattern 230 toward an inside of the electric field generating pattern 230. The strain gradient may induce an electric polarization in the electric field generating pattern 230, thereby causing a local electric field therein. The strain gradient may be characterized using Transmission Electron Microscopy (TEM) techniques, coupled with post-processing methods that enable quantitative mapping of strain and strain gradients at the nanoscale by analyzing variations in lattice spacing or diffraction patterns. The mismatch between the lattice constant of the buffer layer 220 and the lattice constant of the electric field generating pattern 230 may be intentionally made to create the local electric field in the electric field generating pattern 230, which is used to control diffusion of dopants in the active pattern AP.

A material of the first buffer layer 221 and a material of the second buffer layer 222 may be substantially the same. However, the materials of the first buffer layer 221 and the second buffer layer 222 are not limited thereto, and the material of the first buffer layer 221 may differ from the material of the second buffer layer 222 as needed. Accordingly, a strain gradient generated in the first electric field generating pattern 231 may differ from a strain gradient generated in the second electric field generating pattern 232. As a result, the electric field intensity applied to the first source/drain region SD1 may differ from the electric field intensity applied to the second source/drain region SD2.

In one embodiment, the buffer layer 220 may be provided next to the first and/or second source/drain regions SD1 and SD2. The buffer layer 220 may contact a portion of side surfaces of the first and/or second source/drain regions SD1 and SD2.

In one embodiment, the buffer layer 220 may be provided between the electric field generating pattern 230 and the vertical active pattern AP in a plan view. For example, the first buffer layer 221 may be provided between the first electric field generating pattern 231 and the first source/drain region SD1 in a plan view. The second buffer layer 222 may be provided between the second electric field generating pattern 232 and the second source/drain region SD2 in a plan view.

In one embodiment, the buffer layer 220 may surround one surface and side surfaces of the electric field generating pattern 230. The buffer layer 220 may be provided between the electric field generating pattern 230 and the vertical active pattern AP. For example, the buffer layer 220 in contact with the electric field generating pattern 230 may extend between the electric field generating pattern 230 and the vertical active patterns AP.

In one embodiment, the first buffer layer 221 may cover the contact pattern BC. The first buffer layer 221 may vertically extend. The first buffer layer 221 may be provided on a side surface of the contact pattern BC. The first buffer layer 221 may also be provided on the side surface of the vertical active pattern AP. The present disclosure is not limited thereto. In an embodiment, the first buffer layer 221 may be spaced apart from the contact pattern BC. The first buffer layer 221 may be spaced apart from the vertical active pattern AP. In this case, an insulating material may be provided between the first buffer layer 221 and the contact pattern BC or between the first buffer layer 221 and the vertical active pattern AP.

In one embodiment, the second buffer layer 222 may cover the bit line BL. The second buffer layer 222 may be provided on a side surface of the bit line BL. The second buffer layer 222 may also be provided on the side surface of the vertical active pattern AP. The present disclosure is not limited thereto. In an embodiment, the second buffer layer 222 may be spaced apart from the bit line BL. The second buffer layer 222 may be spaced apart from the vertical active pattern AP. In this case, an insulating material may be provided between the second buffer layer 222 and the bit line BL or between the buffer layer 220 and the vertical active pattern AP.

A separation insulating pattern 30 may be provided between the vertical active patterns AP. Specifically, the separation insulating pattern 30 may be provided between the first vertical active patterns AP1 arranged in the first direction D1. The separation insulating pattern 30 may be provided between the second vertical active patterns AP2 arranged in the first direction D1. The separation insulating pattern 30 may electrically isolate the vertical active patterns AP. The separation insulating pattern 30 may include a silicon oxide.

A lower intermediate insulating pattern 22 may be provided between the first vertical active pattern AP1 and the second vertical active pattern AP2. The lower intermediate insulating pattern 22 may electrically isolate the first vertical active pattern AP1 and the second vertical active pattern AP2. The lower intermediate insulating pattern 22 may be provided under the back gate electrode BG. In one embodiment, the lower intermediate insulating pattern 22 may also be provided under the back gate insulating pattern BI. The lower intermediate insulating pattern 22 may include a silicon oxide.

An upper intermediate insulating pattern 24 may be provided between the first vertical active pattern AP1 and the second vertical active pattern AP2. The upper intermediate insulating pattern 24 may electrically isolate the first vertical active pattern AP1 and the second vertical active pattern AP2. The upper intermediate insulating pattern 24 may be provided on the back gate electrode BG. In one embodiment, the upper intermediate insulating pattern 24 may be provided between the back gate insulating pattern BI provided on the other side surface of the first vertical active pattern AP1 and the back gate insulating pattern BI provided on the other side surface of the second vertical active pattern AP2.

A lower insulating pattern 26 may be provided on one side of the vertical active pattern AP. Specifically, the lower insulating pattern 26 may be provided on one side of the second source/drain region SD2 of the vertical active pattern AP. The lower insulating pattern 26 may also be provided between the first vertical active pattern AP1 and the second vertical active pattern AP2. Specifically, the lower insulating pattern 26 may also be provided between the second source/drain regions SD2.

The lower insulating pattern 26 may be provided under the word line WL. In one embodiment, the gate insulating pattern GI may be provided on the lower insulating pattern 26. The lower insulating pattern 26 may include a silicon oxide.

An upper insulating pattern 28 may be provided on the lower insulating pattern 26. The upper insulating pattern 28 may cover the other side surface and an upper surface of the word line WL. Specifically, the upper insulating pattern 28 may be provided on the other side surface of the first word line WL1 and the other side surface of the second word line WL2. The upper insulating pattern 28 may include a silicon oxide.

Each of data storage patterns DSP may be provided on one of the contact patterns BC. Each of the data storage patterns DSP may be electrically connected to each of the first vertical active patterns AP1 and the second vertical active patterns AP2. The data storage patterns DSP may be arranged in a matrix form in the first direction D1 and the second direction D2.

In some embodiments, each of the data storage patterns DSP may include a phase-change material, a magnetic tunnel junction (MTJ) pattern, a variable resistor, or a capacitor.

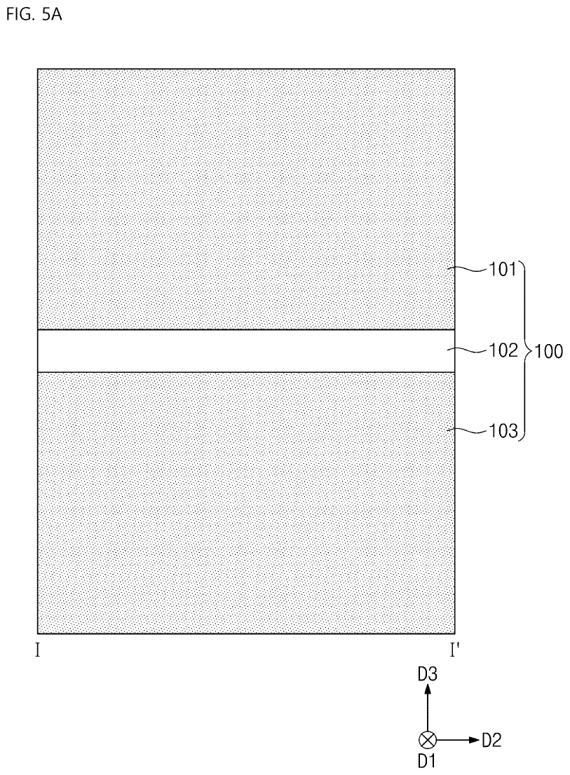

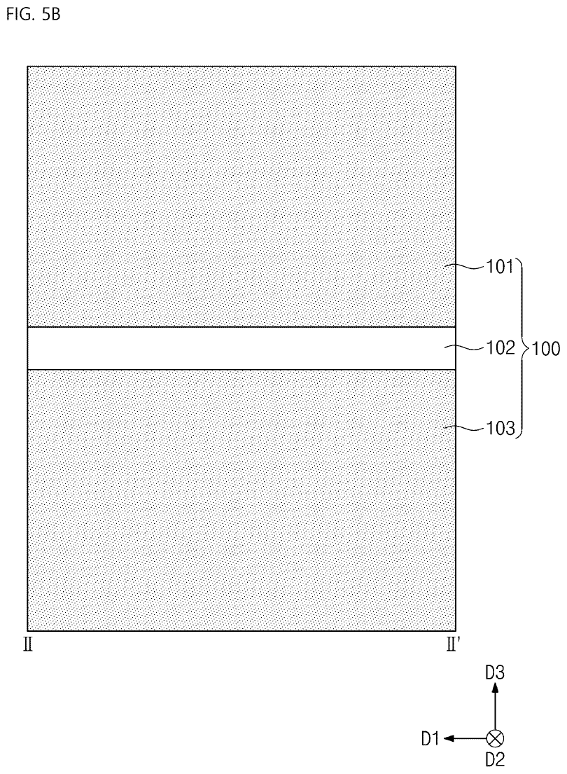

Referring to FIGS. 4A and 4B, when each of the data storage patterns DSP includes a capacitor CAP, each of storage electrodes 242 may be disposed on one of the contact patterns BC, a capacitor dielectric film 244 may conformally cover surfaces of the storage electrodes 242, and a common electrode 246 may be disposed on the capacitor dielectric film 244. The storage electrode 242, the capacitor dielectric film 244, and the common electrode 246 may form the capacitor CAP.

FIGS. 5A to 13A are cross-sectional views for showing a manufacturing method of the semiconductor device 1 according to one embodiment of the present disclosure, and are cross-sectional views corresponding to line I-I′ of FIG. 2.

FIGS. 5B to 13B, 14, and 15 are cross-sectional views for showing the manufacturing method of the semiconductor device 1 according to one embodiment of the present disclosure, and are cross-sectional views corresponding to line II-II′ of FIG. 2.

Referring to FIGS. 5A and 5B, a substrate 100 may be prepared. The substrate 100 may be a semiconductor substrate including silicon, germanium, silicon-germanium, or a compound semiconductor substrate. The present disclosure is not limited thereto. In an embodiment, the substrate 100 may have a silicon on insulator (SOI) structure.

The substrate 100 may include a buried insulating layer 102 and a semiconductor layer 101. The semiconductor layer 101 may be stacked on one surface of the buried insulating layer 102. The substrate 100 may further include a base layer 103 stacked on the other surface of the buried insulating layer 102. For example, the base layer 103, the buried insulating layer 102, and the semiconductor layer 101 may be sequentially stacked.

The semiconductor layer 101 may be a single-crystalline semiconductor material. The buried insulating layer 102 may be a buried oxide. In an embodiment, the buried insulating layer 102 may be an insulating film formed by a chemical vapor deposition method. For example, the buried insulating layer 102 may include a silicon oxide, a silicon nitride, a silicon oxynitride, and/or a low-k material. The base layer 103 may include a material substantially identical to a material of the semiconductor layer 101.

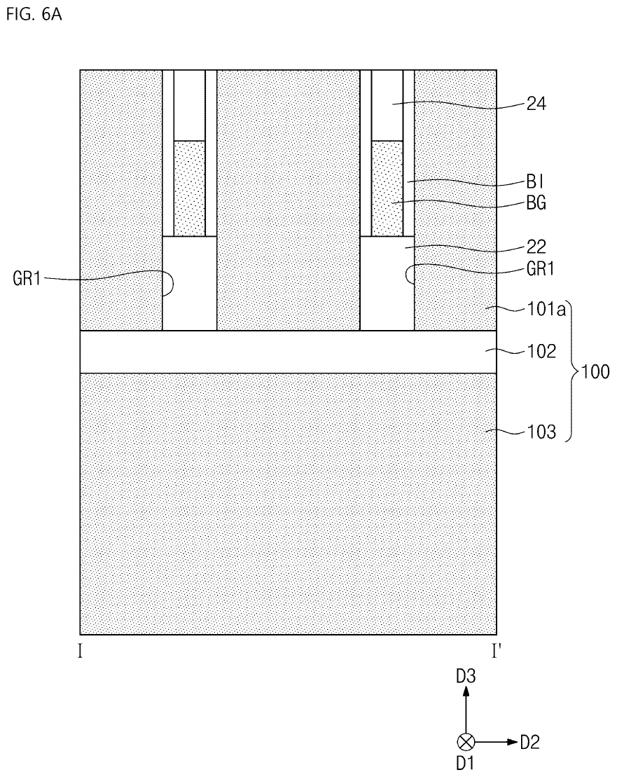

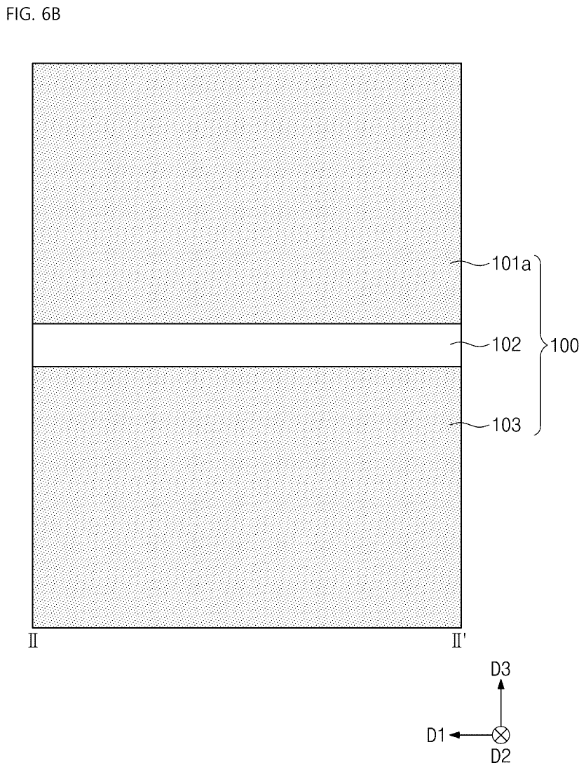

Referring to FIGS. 6A and 6B, first grooves GR1 may be formed in the substrate 100 to form a semiconductor pattern 101a. For example, a patterning process may be performed on one surface of the substrate 100 to form the first grooves GR1. The first grooves GR1 may be formed in the first direction D1. The first grooves GR1 may be spaced apart from each other in the second direction D2. The semiconductor pattern 101a may be defined by the first grooves GR1.

The lower intermediate insulating pattern 22 may be formed to fill the first grooves GR1. The lower intermediate insulating pattern 22 may fill lower portions of the first grooves GR1. For example, after a lower intermediate insulating film is formed to fill the first grooves GR1, the lower intermediate insulating pattern 22 may be formed by etching the filled lower intermediate insulating film. The lower intermediate insulating pattern 22 may expose portions of inner surfaces of the first grooves GR1.

After the lower intermediate insulating pattern 22 is formed, the back gate insulating pattern BI may be formed on portions of the exposed inner surfaces of the first grooves GR1. For example, after the lower intermediate insulating pattern 22 is formed, a back gate insulating film (not shown) conformally covering an upper surface of the lower intermediate insulating pattern 22 and portions of the exposed inner surfaces of the first grooves GR1 may be formed. Subsequently, the back gate insulating film (not shown) may be etched through a blanket anisotropic etching process to form the back gate insulating pattern BI on portions of the inner surfaces of the first grooves GR1.

After the back gate insulating pattern BI is formed, a back gate conductive film (not shown) may be formed in the first grooves GR1. For example, the back gate conductive film (not shown) may be formed to fill the first grooves GR1 in which the back gate insulating pattern BI is formed. Subsequently, the back gate conductive film (not shown) may be etched to form each of the back gate electrodes BG in one of the first grooves GR1.

After the back gate electrodes BG are formed, the upper intermediate insulating pattern 24 may be formed in the first grooves GR1. For example, the upper intermediate insulating pattern 24 may be formed to fill the first grooves GR1 in which the back gate insulating pattern BI and the back gate electrode BG are formed.

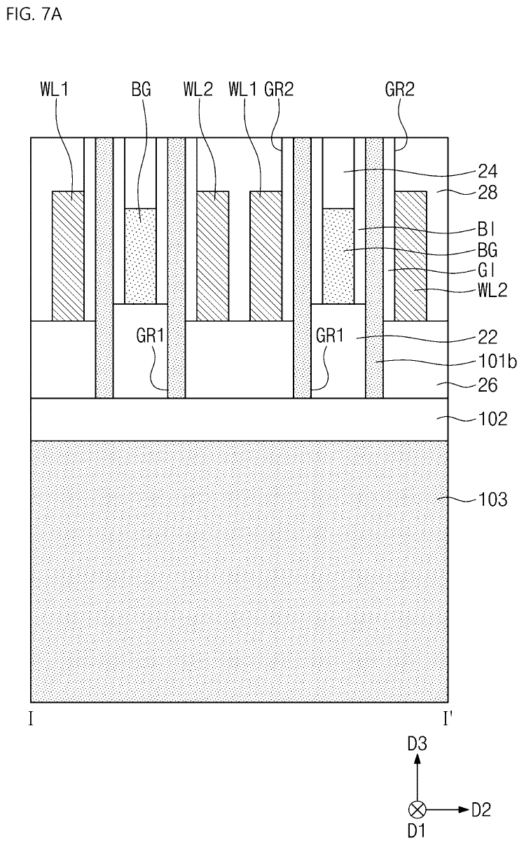

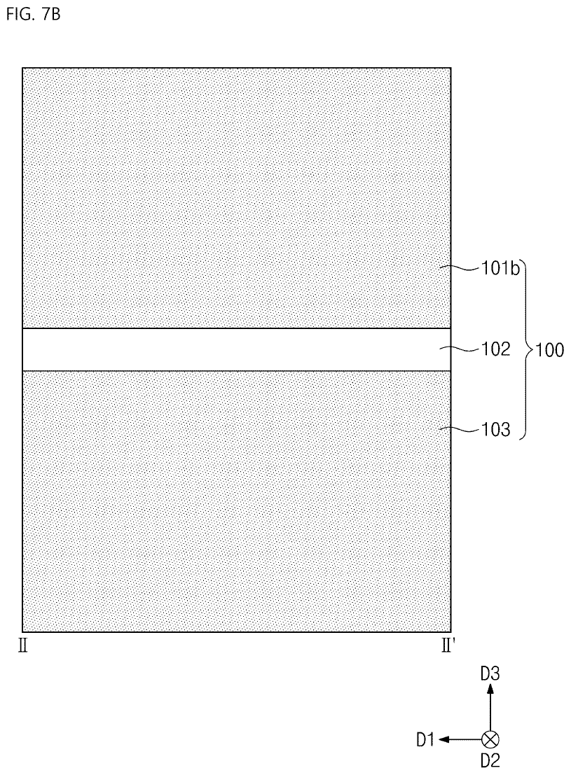

Referring to FIGS. 7A and 7B, second grooves GR2 may be formed in the semiconductor pattern 101a to define preliminary active patterns 101b. The second grooves GR2 may be formed in the first direction D1. The second grooves GR2 may be formed between the first grooves GR1. The first grooves GR1 and the second grooves GR2 may be alternately arranged in the second direction D2 and may be spaced apart from each other. A width of the second groove GR2 may be greater than a width of the first groove GR1. The preliminary active patterns 101b may be defined by the first grooves GR1 and the second grooves GR2.

The lower insulating pattern 26 may be formed to fill the second grooves GR2. The lower insulating pattern 26 may fill lower portions of the second grooves GR2. For example, after a lower insulating film (not shown) is formed to fill the second grooves GR2, the lower insulating pattern 26 may be formed by etching the filled lower insulating film. The lower insulating pattern 26 may expose portions of inner surfaces of the second grooves GR2.

After the lower insulating pattern 26 is formed, the gate insulating pattern GI may be formed on portions of the exposed inner surfaces of the second grooves GR2. For example, after the lower insulating pattern 26 is formed, a gate insulating film (not shown) conformally covering an upper surface of the lower insulating pattern 26 and portions of the exposed inner surfaces of the second grooves GR2 may be formed. Subsequently, the gate insulating film (not shown) may be etched through a blanket anisotropic etching process to form the gate insulating pattern GI on portions of the inner surfaces of the second grooves GR2. Upper surfaces of the gate insulating patterns GI may be coplanar with upper surfaces of the preliminary active patterns 101b.

After the gate insulating pattern GI is formed, the first word lines WL1 and the second word lines WL2 may be formed in the second grooves GR2. For example, after the gate insulating pattern GI is formed, a gate conductive film (not shown) conformally covering an upper surface of the lower insulating pattern 26 and side surfaces of the gate insulating pattern GI may be formed. Subsequently, the gate conductive film (not shown) may be etched through a blanket anisotropic etching process to form the first word lines WL1 and the second word lines WL2 on the side surfaces of the gate insulating pattern GI.

After the word lines WL are formed, the upper insulating pattern 28 may be formed in the second grooves GR2. For example, the upper insulating pattern 28 may be formed to fill the second grooves GR2 in which the lower insulating pattern 26, the gate insulating pattern GI, and the word lines WL are formed. An upper surface of the upper insulating pattern 28 may be coplanar with the upper surfaces of the preliminary active patterns 101b and the upper surfaces of the gate insulating patterns GI.

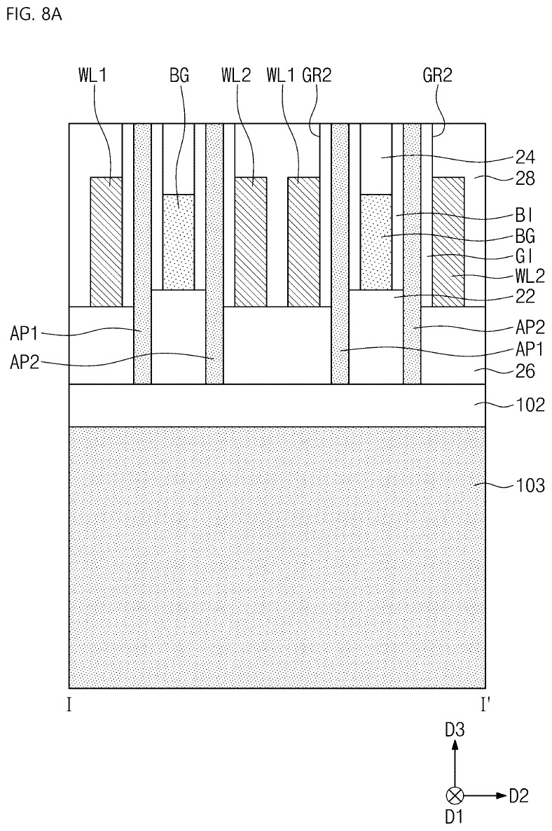

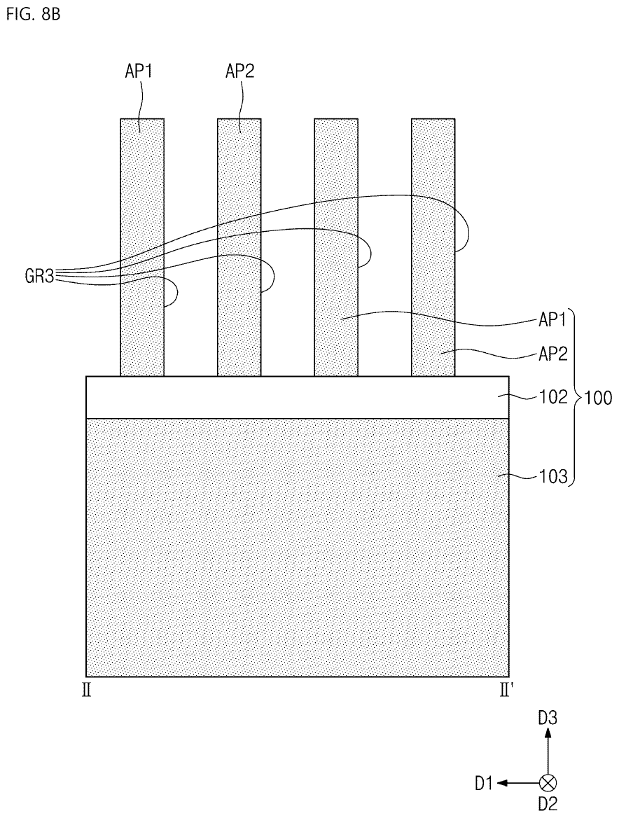

Referring to FIGS. 8A and 8B, third grooves GR3 may be formed in the preliminary active patterns 101b to define the vertical active patterns AP. The third grooves GR3 may be formed in the second direction D2. The third grooves GR3 may be formed between the first grooves GR1 and the second grooves GR2. The first to third grooves GR1, GR2, and GR3 may define the vertical active patterns AP.

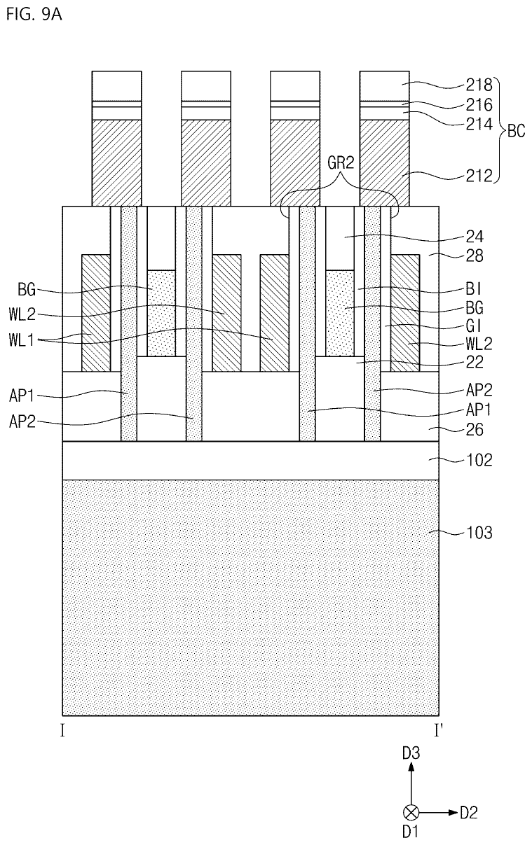

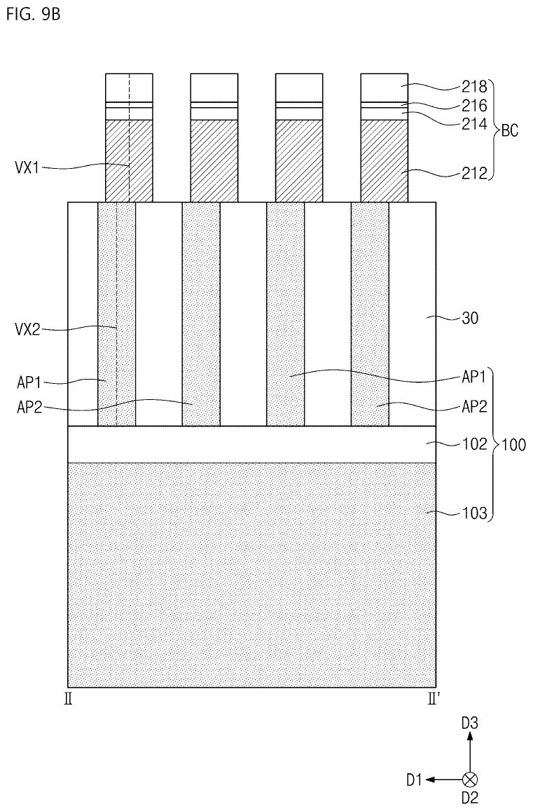

Referring to FIGS. 9A and 9B, the separation insulating pattern 30 filling the third grooves GR3 may be formed. An upper surface of the separation insulating pattern 30 may be coplanar with upper surfaces of the vertical active patterns AP.

After the separation insulating pattern 30 is formed, the contact patterns BC may be formed on the vertical active patterns AP. Specifically, a contact film (not shown) may be formed on the substrate 100 in which the upper insulating pattern 28 and the separation insulating pattern 30 are filled. For example, a buffer semiconductor film (not shown), a first doped semiconductor film (not shown), a first barrier film (not shown), and a first low resistance film (not shown) may be sequentially formed on the substrate 100 in which the upper insulating pattern 28 and the separation insulating pattern 30 are filled. Subsequently, a first hard mask pattern (not shown) having openings may be formed on the contact film (not shown). The openings of the first hard mask pattern (not shown) may overlap portions of the vertical active patterns AP in a plan view. For example, the openings of the first hard mask pattern (not shown) may vertically overlap portions of the vertical active patterns AP. The openings of the first hard mask pattern may expose regions of the contact film to pattern the contact patterns BC.

The contact film (not shown) may be etched using the first hard mask pattern (not shown) as an etching mask to form the contact patterns BC. For example, the buffer semiconductor pattern 212, the first doped semiconductor pattern 214, the first barrier pattern 216, and the first low resistance pattern 218 may be sequentially formed.

The contact patterns BC may be formed on the vertical active patterns AP. In this case, the first virtual vertical central axis VX1 passing through the center of the contact pattern BC may be offset in the direction opposite to the first direction D1 from the second virtual vertical central axis VX2 passing through the center of the vertical active pattern AP.

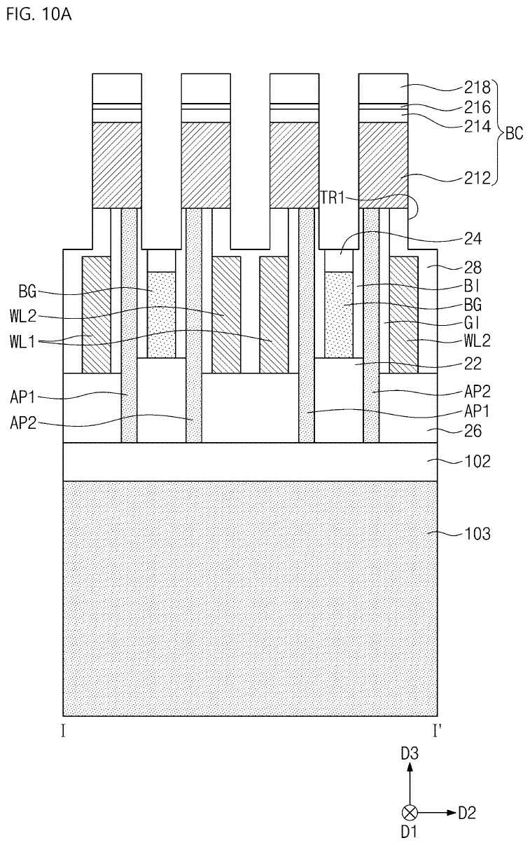

Referring to FIGS. 10A and 10B, a first trench TR1 may be formed in the upper insulating pattern 28. The first trench TR1 may be formed in the separation insulating pattern 30. The first trench TR1 may be formed by recessing the upper surface of the upper insulating pattern 28 and the upper surface of the separation insulating pattern 30 exposed between the contact patterns BC. For example, the first trench TR1 may be formed by etching the upper insulating pattern 28 and the separation insulating pattern 30 using the contact patterns BC and the vertical active patterns AP as an etching mask. During this process, a portion of the back gate insulating pattern BI may also be etched.

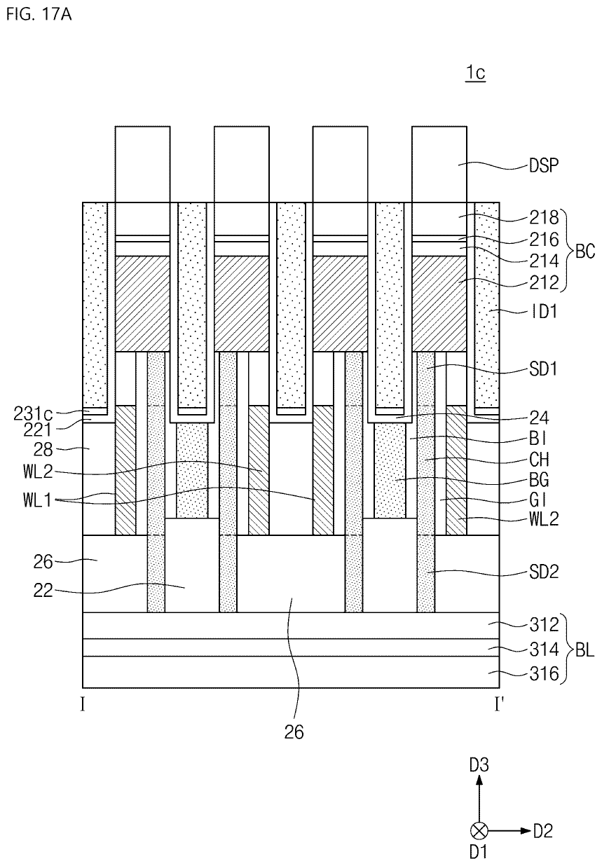

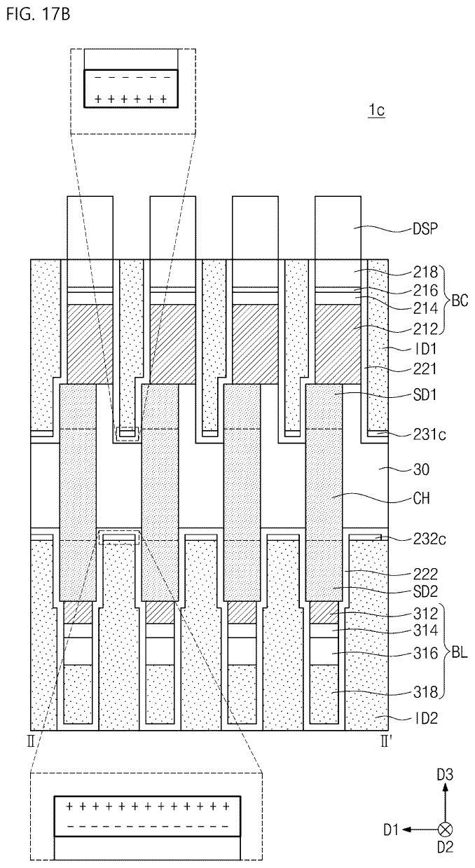

The first trench TR1 may be formed above the back gate electrode BG. The first trench TR1 may also be formed above the word lines WL. For example, a bottom surface of the first trench TR1 may be formed above an upper end of the word line WL. The bottom surface of the first trench TR1 may be formed above an upper end of the back gate electrode BG. The present disclosure is not limited thereto. In an embodiment, referring to FIGS. 17A and 17B, the bottom surface of the first trench TR1 may be formed between the upper end of the word line WL and the upper end of the back gate electrode BG as needed.

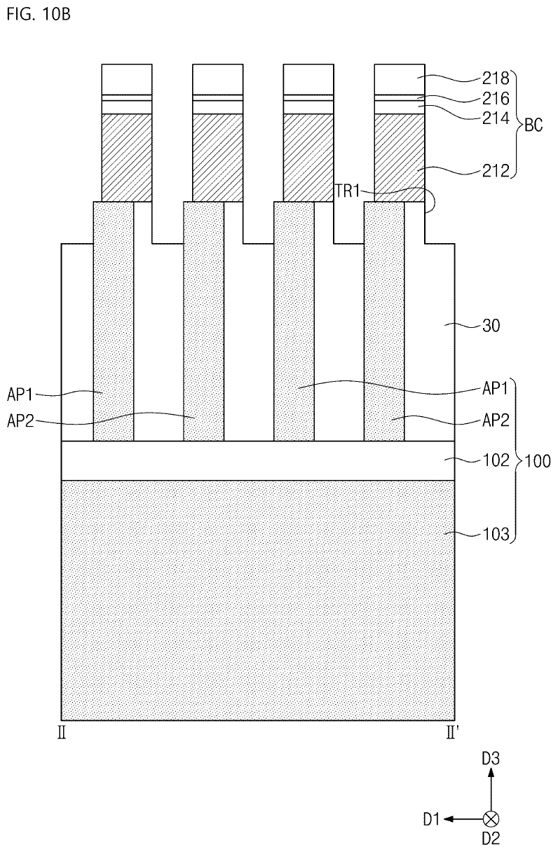

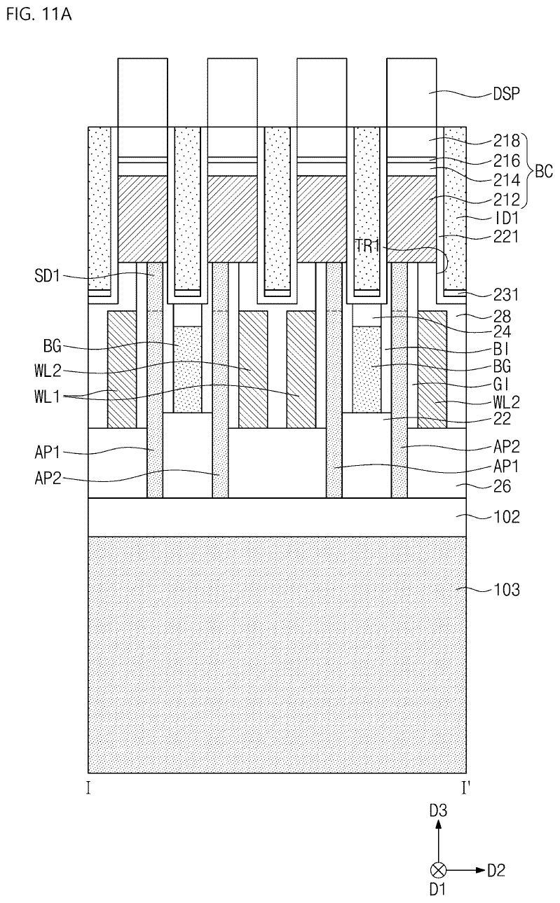

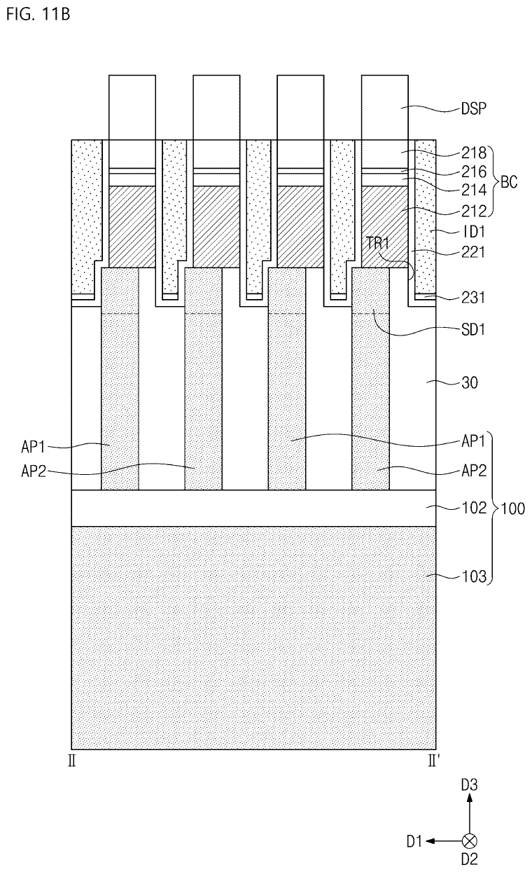

Referring to FIGS. 11A and 11B, the first buffer layer 221 conformally covering the contact patterns BC and the first trenches TR1 formed between the contact patterns BC may be formed. The first buffer layer 221 may cover the bottom surfaces and inner surfaces of the first trenches TR1. The first buffer layer 221 may extend to cover side surfaces of the contact patterns BC. The first buffer layer 221 formed on upper surfaces of the contact patterns BC may be removed.

After the first buffer layer 221 is formed, a first electric field generating film (not shown) may be formed in the first trench TR1. The first electric field generating film (not shown) may be formed to fill the first trenches TR1. The first electric field generating film (not shown) may be formed to fill spaces between the contact patterns BC. For example, after the first electric field generating film (not shown) is formed to fill the first trenches TR1 and the spaces between the contact patterns BC, the first electric field generating pattern 231 may be formed by etching the filled first electric field generating film (not shown). The first electric field generating pattern 231 may expose a portion of the first buffer layer 221 covering the inner surfaces of the first trenches TR1.

After the first electric field generating pattern 231 is formed in the first trench TR1, dopants may be implanted into upper portions of the vertical active patterns AP. For example, the dopants may be implanted through a plasma doping process or an ion implantation process. Thereafter, an annealing process may be performed to activate the implanted dopants. In this case, an electric field generated from the first electric field generating pattern 231 may assist the diffusion of the dopants activated by the annealing process. In the annealing process, dopants may be activated to be in charged states such as positively charged ions such as P⁺ and negatively charged ions such as B⁻. Depending on the diffusion direction and charged states of the dopants, the electric field may assist or suppress the diffusion.

The first interlayer insulating film ID1 may be formed. The first interlayer insulating film ID1 may be formed to fill the inside of the first trench TR1 in which the electric field generating pattern 230 is formed. The first interlayer insulating film ID1 may be formed to fill the spaces between the contact patterns BC.

After the contact patterns BC are formed, the data storage patterns DSP may be formed on the contact patterns BC.

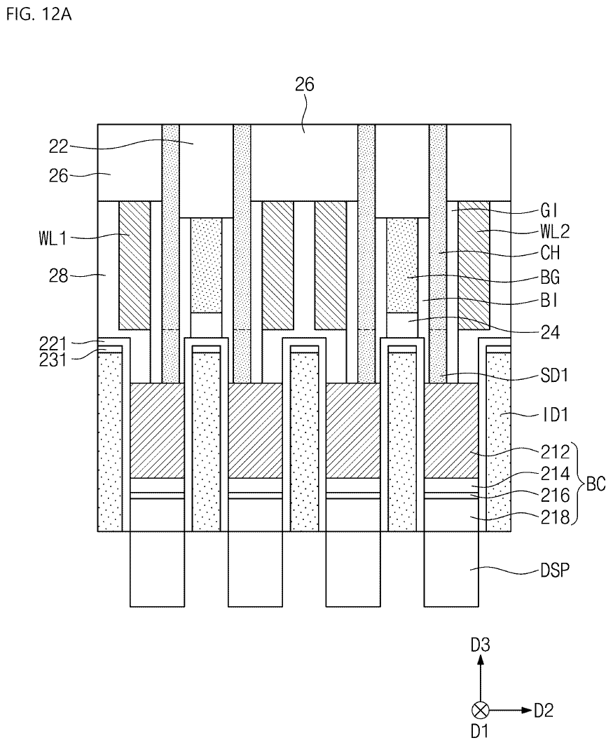

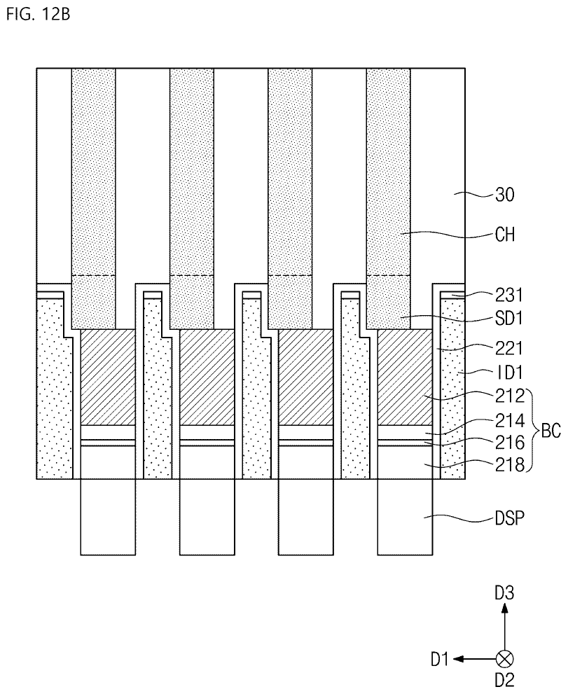

Referring to FIGS. 12A and 12B, the substrate 100 in which the buffer layer 220 and the electric field generating pattern 230 are formed may be flipped. Subsequently, the base layer 103 of the substrate 100 may be removed, and then the buried insulating layer 102 may be removed. For example, the base layer 103 may be removed using a wet etching process or a grinding process. The buried insulating layer 102 may be removed using a wet etching process or an isotropic dry etching process. By removing the base layer 103 and the buried insulating layer 102, lower surfaces of the vertical active patterns AP, a lower surface of the lower insulating pattern 26, a lower surface of the lower intermediate insulating pattern 22, and a lower surface of the separation insulating pattern 30 may be exposed.

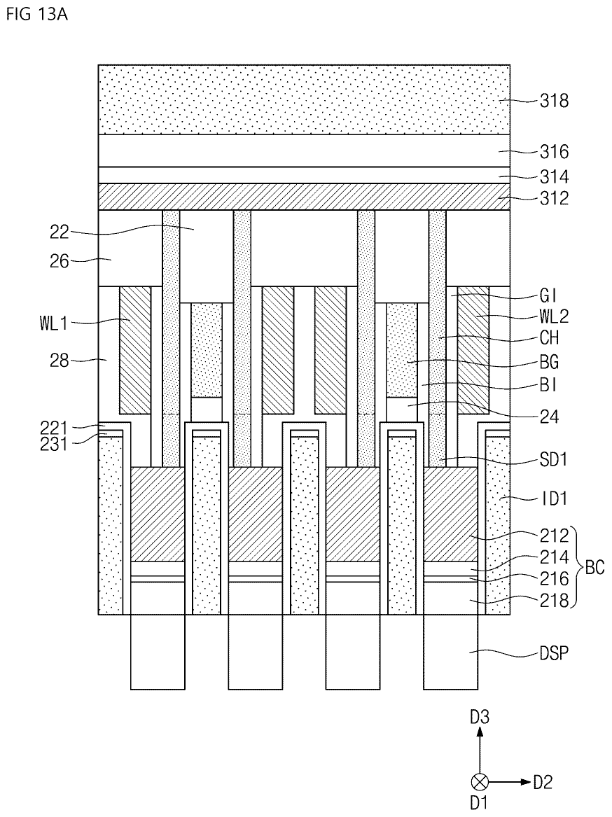

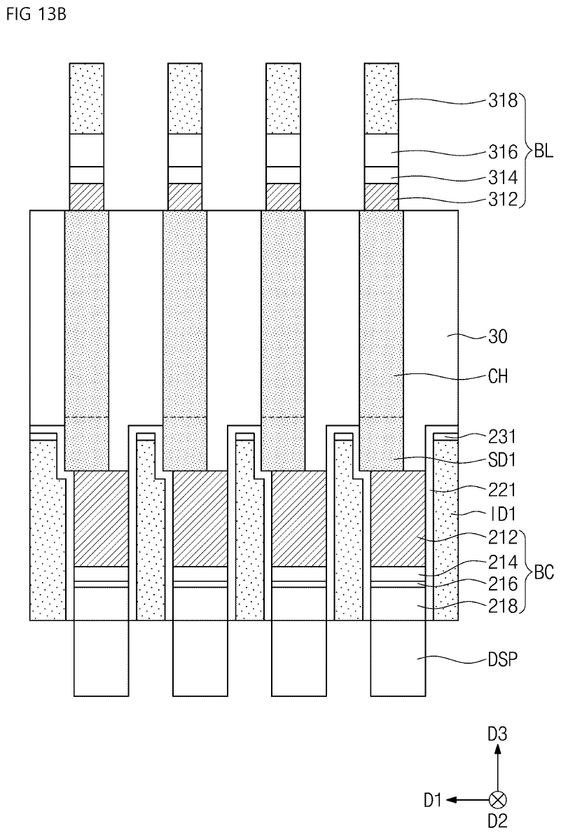

Referring to FIGS. 13A and 13B, the bit lines BL may be formed on the lower surfaces of the vertical active patterns AP. Specifically, a bit line film (not shown) may be formed on the lower surfaces of the vertical active patterns AP, the lower surface of the lower insulating pattern 26, the lower surface of the lower intermediate insulating pattern 22, and the lower surface of the separation insulating pattern 30 that are exposed. For example, a second doped semiconductor film (not shown), a second barrier film (not shown), and a second low resistance film (not shown) may be sequentially formed on the lower surfaces of the vertical active patterns AP, the lower surface of the lower insulating pattern 26, the lower surface of the lower intermediate insulating pattern 22, and the lower surface of the separation insulating pattern 30 that are exposed. Subsequently, a second hard mask pattern (not shown) having openings may be formed on the bit line film (not shown). The openings of the second hard mask pattern (not shown) may overlap the vertical active patterns AP in a plan view. For example, the openings of the second hard mask pattern (not shown) may vertically overlap the vertical active patterns AP. The openings of the second hard mask pattern may expose regions of the bit line film to pattern the bit lines BL.

The bit line film (not shown) may be etched using the second hard mask pattern (not shown) as an etching mask to form the bit lines BL. The bit lines BL may be formed on the vertical active patterns AP. For example, the second doped semiconductor pattern 312, the second barrier pattern 314, and the second low resistance pattern 316 may be sequentially formed. The bit lines BL may extend in the second direction D2.

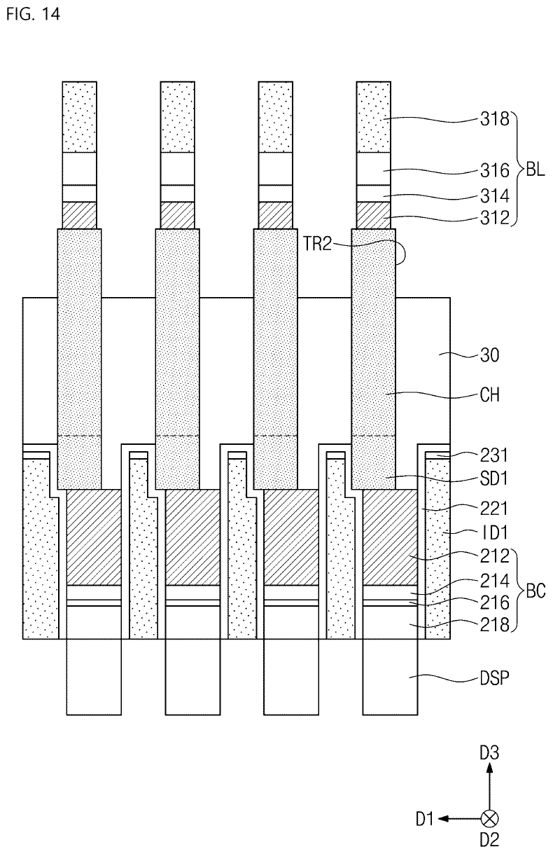

Referring to FIG. 14, a second trench TR2 may be formed in the lower insulating pattern 26 and the separation insulating pattern 30. The second trench TR2 may be formed by recessing the lower surface of the lower insulating pattern 26 and the lower surface of the separation insulating pattern 30 that are exposed between the bit lines BL. For example, the second trench TR2 may be formed by etching the lower insulating pattern 26 and the separation insulating pattern 30 using the bit lines BL and the vertical active patterns AP as an etching mask.

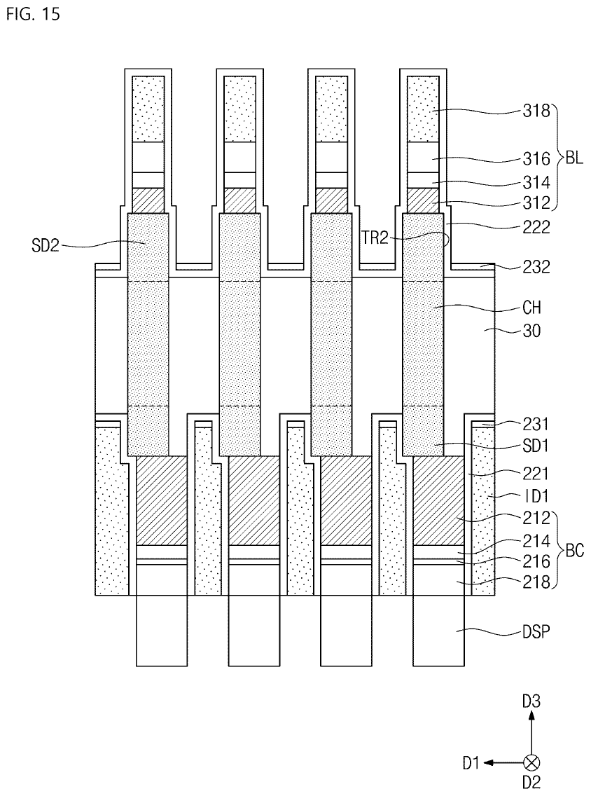

Referring to FIG. 15, the second buffer layer 222 conformally covering the bit lines BL and the second trenches TR2 formed between the bit lines BL may be formed. The second buffer layer 222 may cover bottom surfaces and inner surfaces of the second trenches TR2. The second buffer layer 222 may extend to cover the bit lines BL.

After the second buffer layer 222 is formed, a second electric field generating film (not shown) may be formed in the second trench TR2. The second electric field generating film (not shown) may be formed to fill the second trenches TR2. The second electric field generating film (not shown) may be formed to fill spaces between the bit lines BL. For example, after the second electric field generating film (not shown) is formed to fill the second trenches TR2 and the spaces between the bit lines BL, the second electric field generating pattern 232 may be formed by etching the filled second electric field generating film (not shown). The second electric field generating pattern 232 may expose a portion of the second buffer layer 222 covering the inner surfaces of the second trenches TR2.

After the second electric field generating pattern 232 is formed in the second trench TR2, dopants may be implanted into lower portions of the vertical active patterns AP. For example, the dopants may be implanted through a plasma doping process or an ion implantation process. Thereafter, an annealing process may be performed to activate the implanted dopants. In this case, an electric field generated from the second electric field generating pattern 232 may assist the diffusion of the dopants activated by the annealing process.

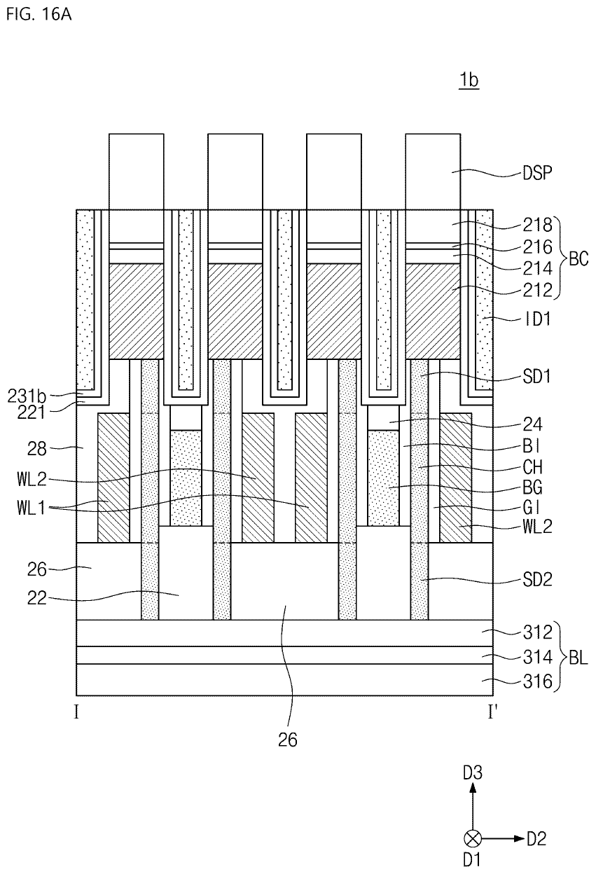

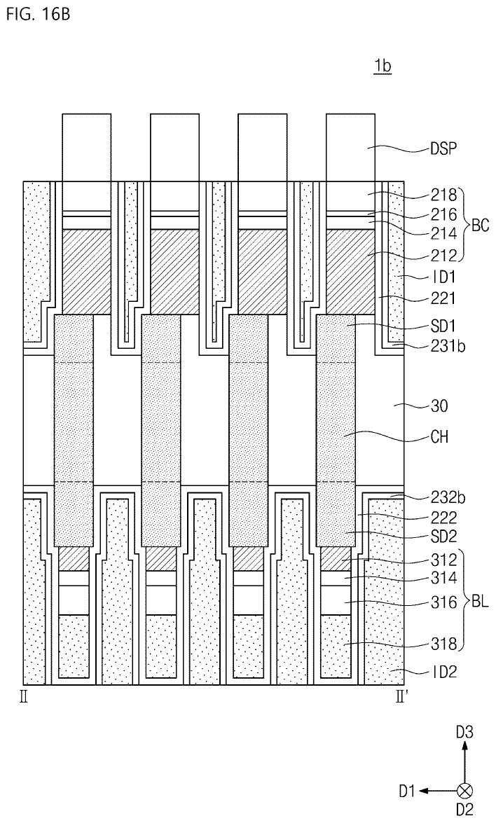

FIG. 16A is a cross-sectional view of a semiconductor device 1b according to one embodiment of the present disclosure, and is a cross-sectional view corresponding to line I-I′ of FIG. 2. FIG. 16B is a cross-sectional view of the semiconductor device 1b according to one embodiment of the present disclosure, and is a cross-sectional view corresponding to line II-II′ of FIG. 2.

Most components and materials forming components, which constitute the semiconductor device 1b described below are substantially the same as or similar to components of the semiconductor device 1 described above in FIGS. 1 to 3B. Therefore, for the convenience of explanation, differences from the above-described semiconductor device 1 will be mainly described.

Referring to FIGS. 16A and 16B, in one embodiment, an electric field generating pattern 230b may extend along the buffer layer 220. For example, a first electric field generating pattern 231b may be provided on the first buffer layer 221 extending toward the contact pattern BC. A second electric field generating pattern 232b may be provided on the second buffer layer 222 extending toward the bit line BL. Therefore, the first electric field generating pattern 231b may cover an inner surface of the extended first buffer layer 221 and the second electric field generating pattern 232b may cover an inner surface of the extended second buffer layer 222. For example, the first electric field generating pattern 231b may be provided on a bottom surface and the inner surface of the first buffer layer 221. The second electric field generating pattern 232b may be provided on a bottom surface and the inner surface of the second buffer layer 222.

The first electric field generating pattern 231b may be provided between the first source/drain regions SD1. The second electric field generating pattern 232b may be provided between the second source/drain regions SD2. The first electric field generating pattern 231b may also be provided between the contact patterns BC. The first buffer layer 221 and the first electric field generating pattern 231b may be sequentially stacked on one side surfaces of neighboring contact patterns BC. In this case, the first interlayer insulating film ID1 may be provided between the first electric field generating patterns 231b provided on one side surfaces of the neighboring contact patterns BC.

The second buffer layer 222 and the second electric field generating pattern 232b may be provided between the bit lines BL. The second buffer layer 222 and the second electric field generating pattern 232b may be sequentially stacked on one side surface of neighboring bit lines BL. In this case, a second interlayer insulating film ID2 may be provided between the second electric field generating patterns 232b provided on one side surface of the neighboring bit lines BL.

FIG. 17A is a cross-sectional view of a semiconductor device 1c according to one embodiment of the present disclosure, and is a cross-sectional view corresponding to line I-I′ of FIG. 2. FIG. 17B is a cross-sectional view of the semiconductor device 1c according to one embodiment of the present disclosure, and is a cross-sectional view corresponding to line II-II′ of FIG. 2.

Most components and materials forming components, which constitute the semiconductor device 1c described below are substantially the same as or similar to components of the semiconductor device 1 described above in FIGS. 1 to 3B. Therefore, for the convenience of explanation, differences from the above-described semiconductor device 1 will be mainly described.

Referring to FIGS. 17A and 17B, in one embodiment, a first electric field generating pattern 231c may be provided next to the vertical active pattern AP but may not be provided next to the first source/drain region SD1 in the first direction D1 and the second direction D2. A second electric field generating pattern 232c may be provided next to the vertical active pattern AP but may not be provided next to the second source/drain region SD2. For example, the first and/or second electric field generating patterns 231c and 232c may be provided next to the channel region CH. Specifically, the first and/or second electric field generating patterns 231c and 232c may be provided between an upper end and a lower end of the channel region CH. For example, the first electric field generating pattern 231c and the second electric field generating pattern 232c may each be provided next to the channel region CH.

In this case, a direction of an electric field generated from the electric field generating pattern 230c may be opposite to a direction of the electric field generated from the electric field generating pattern 230 of FIGS. 3A and 3B. For example, a polarization state generated in the electric field generating pattern 230c may be opposite to a polarization state generated in the electric field generating pattern 230 of FIGS. 3A and 3B.

For example, referring to FIGS. 3A and 3B, the electric field generated from the first electric field generating pattern 231 may promote the diffusion of dopants in the first source/drain region SD1. The electric field generated from the second electric field generating pattern 232 may promote the diffusion of dopants in the second source/drain region SD2. For example, when the dopants diffuse and junctions of the first and/or second source/drain regions SD1 and SD2 are established, the electric field generated from the first and/or second electric field generating patterns 231 and 232 can promote the diffusion of the dopants so that the junctions of the first and/or second source/drain regions SD1 and SD2 can reach a target level.

Conversely, for example, referring to FIGS. 17A and 17B, the electric field generated from the first electric field generating pattern 231c may suppress the diffusion of dopants in the first source/drain region SD1. The electric field generated from the second electric field generating pattern 232c may suppress the diffusion of dopants in the second source/drain region SD2. For example, when the dopants diffuse and the junctions of the first and/or second source/drain regions SD1 and SD2 are established at the target level, the electric field generated from the first and/or second electric field generating patterns 231c and 232c may suppress the diffusion of the dopants.

According to embodiments of the present disclosure, an electric field generating pattern can be provided next to a vertical active pattern and a buffer layer can generate electrical polarization in the electric field generating pattern. Accordingly, the electric field generating pattern can generate an electric field by itself. The electric field generated by the electric field generating pattern can control the diffusion of dopants of a source/drain region in the vertical active pattern. As a result, a junction between the source/drain region and a channel region can be formed at a target level.

According to embodiments of the present disclosure, the electric field generating pattern and the buffer layer that are provided next to the source/drain region can generate an electric field applied to the dopants doped in the source/drain region. Therefore, the electric field generating pattern and the buffer layer can assist or suppress the diffusion of the dopants of the source/drain region. Accordingly, a level at which the junction between the channel region and the source/drain region is formed can be controlled.

According to embodiments of the present disclosure, the electric field generating pattern and the buffer layer can generate an electric field by themselves. Specifically, due to the difference in characteristics (such as a lattice constant) between the buffer layer and the electric field generating pattern, a strain gradient can occur in the electric field generating pattern and polarization can occur in the electric field generating pattern.

According to embodiments of the present disclosure, due to a contact pattern offset from the vertical active pattern, a trench in which the buffer layer and the electric field generating pattern are filled can be formed closer to the source/drain region. Therefore, the buffer layer and the electric field generating pattern can be formed closer to the source/drain region, and the intensity of an electric field applied to the source/drain region can be increased.

According to embodiments of the present disclosure, since the electric field generating pattern surrounds the vertical active pattern in a plan view, the electric field can be evenly applied to the vertical active pattern in all directions. Accordingly, the level at which the junction between the channel region and the source/drain region is formed can become much more constant.

The above-described contents are specific embodiments for implementing the present disclosure. In addition to the above-described embodiments, the present disclosure will also include embodiments that can be simply designed around or easily changed. The present disclosure will also include technologies that can be implemented by being easily modified using the embodiments. Therefore, the scope of the present disclosure should not be limited to the above-described embodiments, but should be defined not only by the appended claims but also by the equivalents of the claims of the present disclosure.

What is claimed is:

1. A semiconductor device comprising:
a bit line;
a vertical active pattern on an upper surface of the bit line and extending lengthwise in a vertical direction perpendicular to the upper surface of the bit line;
a word line extending lengthwise in a first horizontal direction and overlapping a first side surface of the vertical active pattern in a second horizontal direction different from the first horizontal direction, the first horizontal direction and the second horizontal direction being perpendicular to the vertical direction;
a gate Insulating pattern provided in a space between the word line and the first side surface of the vertical active pattern;
an electric field generating pattern provided next to the vertical active pattern in the first horizontal direction and the second horizontal direction; and
a buffer layer located in a space between the vertical active pattern and the electric field generating pattern in the first horizontal direction and the second horizontal direction,
wherein the electric field generating pattern has a strain gradient from an interface between the buffer layer and the electric field generating pattern toward an inside of the electric field generating pattern, and
wherein the strain gradient induces an electric polarization in the electric field generating pattern.

2. The semiconductor device of claim 1,
wherein the vertical active pattern includes:
a first source/drain region that is an upper side portion of the vertical active pattern;
a second source/drain region that is a lower side portion of the vertical active pattern; and
a channel region located between the first source/drain region and the second source/drain region in the vertical direction and overlapping the word line in the second horizontal direction, and
wherein the electric field generating pattern is provided next to at least one of the first source/drain region and the second source/drain region in the first horizontal direction and the second horizontal direction.

3. The semiconductor device of claim 1,
wherein the buffer layer includes a portion overlapping the vertical active pattern in the vertical direction.

4. The semiconductor device of claim 1, further comprising:
a contact pattern on the vertical active pattern,
wherein the contact pattern does not overlap the electric field generating pattern in the vertical direction.

5. The semiconductor device of claim 1,
wherein the buffer layer contacts the electric field generating pattern.

6. The semiconductor device of claim 2, further comprising:
a contact pattern provided on the first source/drain region,
wherein the contact pattern partially overlaps the first source/drain region.

7. The semiconductor device of claim 6,
wherein a first virtual vertical central axis of the contact pattern is offset, in the first horizontal direction, from a second virtual vertical central axis of the vertical active pattern.

8. The semiconductor device of claim 2, further comprising:
a contact pattern disposed on the vertical active pattern,
wherein the electric field generating pattern is located next to the first source/drain region in the first horizontal direction and the second horizontal direction,
wherein the buffer layer includes a portion located between the electric field generating pattern and the first source/drain region,
wherein the contact pattern contacts a first portion of an upper surface of the first source/drain region, and
wherein the buffer layer contacts a second portion of the upper surface of the first source/drain region and a portion of a side surface of the first source/drain region.

9. The semiconductor device of claim 1,
wherein the electric field generating pattern surrounds the vertical active pattern when viewed in a plan view.

10. The semiconductor device of claim 9,
wherein the buffer layer is provided between the electric field generating pattern and the vertical active pattern when viewed in the plan view.

11. The semiconductor device of claim 1,
wherein the buffer layer includes SrTiO₃, SrRuO₃, W, Ti, or Au.

12. The semiconductor device of claim 1,
wherein the electric field generating pattern includes BiFeO₃, TiO₂, BaTiO₃, BaSrTiO₃, PbMgNbO₃, PbSrTiO₃, or Pb(Zr, Ti)O₃.

13. The semiconductor device of claim 2,
wherein the second source/drain region is disposed on the upper surface of the bit line,
wherein the electric field generating pattern is provided next to the second source/drain region in the first horizontal direction and the second horizontal direction, and
wherein the buffer layer covers a side surface of the bit line and a lower surface thereof.

14. The semiconductor device of claim 13, further comprising:
a contact pattern disposed on the vertical active pattern,
wherein the electric field generating pattern is located next to the second source/drain region in the first horizontal direction and the second horizontal direction,
wherein the buffer layer includes a portion located between the electric field generating pattern and the second source/drain region,
wherein the bit line contacts a first portion of the lower surface of the second source/drain region, and
wherein the buffer layer contacts a second portion of the lower surface of the second source/drain region and a portion of a side surface of the second source/drain region.

15. A semiconductor device comprising:
a plurality of first vertical active patterns arranged in a first direction;
a plurality of second vertical active patterns arranged in the first direction, the plurality of second vertical active patterns being spaced apart from the plurality of first vertical active patterns in a second direction intersecting the first direction, wherein each first vertical active pattern of the plurality of first vertical active patterns extends lengthwise in a vertical direction perpendicular to the first direction and the second direction;
a first word line provided next to a first side of each first vertical active pattern of the plurality of first vertical active patterns and extending lengthwise in the first direction;
a second word line provided next to a first side of each second vertical active pattern of the plurality of second vertical active patterns and extending lengthwise in the first direction;
a gate insulating pattern provided between the first word line and each first vertical active pattern of the plurality of first vertical active patterns and between the second word line and each second vertical active pattern of the plurality of second vertical active patterns;
an electric field generating pattern adjacent to the plurality of first vertical active patterns and the plurality of second vertical active patterns; and
a buffer layer contacting the electric field generating pattern,
wherein the electric field generating pattern has a strain gradient from an interface between the buffer layer and the electric field generating pattern toward an inside of the electric field generating pattern, and
wherein the strain gradient induces an electric polarization in the electric field generating pattern.

16. The semiconductor device of claim 15,
wherein the electric field generating pattern is adjacent to an upper portion of each first vertical active pattern of the plurality of first vertical active patterns and an upper portion of each second vertical active pattern of the plurality of second vertical active patterns, and
wherein the buffer layer extends between the electric field generating pattern and the upper portion of each first vertical active pattern and between the electric field generating pattern and the upper portion of each second vertical active pattern.

17. The semiconductor device of claim 15,
wherein the electric field generating pattern is adjacent to a lower portion of each first vertical active pattern of the plurality of first vertical active patterns and a lower portion of each second vertical active pattern of the plurality of second vertical active patterns, and
wherein the buffer layer extends between the electric field generating pattern and the lower portion of each first vertical active pattern and between the electric field generating pattern and the lower portion of each second vertical active pattern.

18. The semiconductor device of claim 16, further comprising:
a plurality of contact patterns provided on the plurality of first vertical active patterns and the plurality of second vertical active patterns,
wherein a first virtual vertical central axis passing through a center of each contact pattern of the plurality of contact patterns is offset, in the first direction, from a corresponding vertical active pattern among the plurality of first vertical active patterns and the plurality of second vertical active patterns.

19. A semiconductor device comprising:
a vertical active pattern extending lengthwise in a vertical direction;
a word line extending lengthwise in first direction and overlapping a first side surface of the vertical active pattern in a second direction different from the first direction, wherein the vertical direction is perpendicular to the first direction and the second direction;
a gate insulating pattern provided in a space between the word line and the first side surface of the vertical active pattern;
an electric field generating pattern provided next to the vertical active pattern in the first direction and the second direction; and
a buffer layer located in a space between the vertical active pattern and the electric field generating pattern,
wherein the electric field generating pattern has a strain gradient from an interface between the buffer layer and the electric field generating pattern toward an inside of the electric field generating pattern,
wherein the strain gradient induces an electric polarization in the electric field generating pattern,
wherein the vertical active pattern includes:
a first source/drain region that is an upper side portion of the vertical active pattern;
a second source/drain region that is a lower side portion of the vertical active pattern; and
a channel region located between the first source/drain region and the second source/drain region and including a portion that overlaps the word line in a horizontal direction, and
wherein the electric field generating pattern is provided next to the channel region.

20. The semiconductor device of claim 19,
wherein the buffer layer contacts the electric field generating pattern.
